(19) United States
(12) Patent Application Publication
(10) Pub. No.: US 2004/0132245 A1
(43) Pub. Date: Jul. 8, 2004

(54) METHOD OF FABRICATING A DRAM CELL

(76) Inventor: Pi-Chun Juan, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 10/248,280

(22) Filed: Jan. 6, 2003

(51) Int. Cl. H01L 21/8242

(52) U.S. Cl. 438/243; 438/239; 438/248

(57) ABSTRACT

A dynamic random access memory (DRAM) cell is disclosed. First, a dual damascene trench is formed in a silicon substrate, and the dual damascene trench is composed of an upper first trench and a lower second trench. Then, a buried plate is formed in the silicon substrate to surround the second trench. A node dielectric is formed on a surface of the buried plate, and a collar dielectric is formed on portions of the silicon substrate in the second trench. A buried strap is formed in the second trench, and a trench top oxide (TTO) is formed on the buried strap. Finally, a threshold voltage of a metal oxide semiconductor (MOS) transistor of the memory cell is adjusted, and a source, a drain and a gate of the MOS transistor are formed.

### BACKGROUND OF INVENTION

1. Field of the Invention

The present invention relates to a method of fabricating a dynamic random access memory (DRAM) cell, and more particularly, to a method of fabricating a vertical transistor comprising a dual damascene trench.

2. Description of the Prior Art

A dynamic random access memory (DRAM) cell is composed of a metal oxide semiconductor (MOS) transistor connected to a capacitor. MOS transistor comprises a gate, a first and a second doped region. The two doped regions are of the identical structure and are used as a source and a drain depending on the operational situation of the MOS transistor. As dimensions of these devices decrease, a vertical transistor is utilized to increase the integration of the integrated circuits (IC). The source/drain (S/D) and the gate of the conventional transistor are formed horizontally, and the S/D and the gate of the vertical transistor are formed perpendicularly with the conventional transistor. Therefore, a vertical channel is formed to reduce crabwise areas of the MOS transistor and increase the integration of the semiconductor devices.

FIG. 1 through FIG. 5 are schematic diagrams in a conventional method of fabricating a DRAM cell. Referring to FIG. 1, a semiconductor wafer 10 having a silicon substrate 12 is provided and a pad stack 16 is formed on the silicon substrate 12. The pad stack 16 is composed of a pad oxide layer 18 and a silicon nitride layer 20. First, a conventional photolithographic and etching process is performed to form a trench 14 in the silicon substrate 12. Then, an arsenic silicate glass (ASG) diffusion technique is performed to form a buried plate (not shown) in the silicon substrate 12 underlying the trench 14. A dielectric layer (not shown), a collar oxide layer 22 and a buried strap 28 are formed on the buried plate. The buried strap 28 is used as a storage node, and the dielectric layer and the collar oxide layer 22 are used to isolate the buried plate from the storage node 28. The buried strap 28, the dielectric layer, the collar oxide layer 22, and the buried plate underlying the dielectric layer and the collar oxide layer 22 complete a capacitor structure.

Referring to FIG. 2, an insulating layer, namely a trench top oxide (TTO) layer 32 is formed on the buried strap 28 in the trench 14, and a portion of sidewall of the trench 14 is exposed and used as a vertical channel of a vertical transistor. Afterwards, a tilt-angle ion implantation process 23 and 23 is performed to implant ions into a surface of the silicon substrate 12 and the exposed sidewall of the trench 14, so as to adjust a threshold voltage of the vertical transistor.

Referring to FIG. 3, a gate oxide layer 34 and a gate polysilicon layer 36 are deposited on the semiconductor wafer 10. Referring to FIG. 4, a shallow trench isolation (STI) process is performed to form a shallow trench (not shown) overlapping with a portion of the trench 14. The shallow trench has a depth larger than a depth of the TTO layer 32, thus a portion of the buried strap 28 is exposed in the shallow trench. Then, a silicon oxide compound is filled in the shallow trench to form a shallow trench isolation layer 42. Following this, a polysilicon layer 36 and a top protection layer 37 are formed on the semiconductor wafer 10.

Referring to FIG. 5, a gate structure, a source 40, a drain 41, a spacer 46, a bit line contact 52 and a bit line 54 of the vertical transistor are formed by a subsequent photolithographic process, etching process, ion implantation process, thermal diffusion process and so on to complete the fabrication of the vertical transistor and the periphery circuit devices.

Although the conventional vertical transistor reduces the crabwise areas of the MOS transistor, a critical dimension (CD) of line width of the trench is still limited by are solution limit of the optical exposure tool, and especially when the trench line width is below 0.1 micrometers (μm), the process is hard to controll. In addition, a poly recess etching process is utilized many times to form a bottom capacitor structure, the collar oxide 22, the buried strap 28 and the TTO layer 32. When the trench line width is too small, a depth of the etched polysilicon layer is not precisely controlled and a depth deviation is induced in the subsequent collar oxide layer 22 and TTO layer 32 structures. Thus, a channel length of the gate is not identical with a standard channel length to affect the electrical property and reduce the product reliability.

### SUMMARY OF INVENTION

It is therefore an objective of the present invention to provide a method of fabricating a vertical transistor comprising a dual damascene trench and prevent the above-mentioned line width problems.

A preferred embodiment of the present invention begins with forming a dual damascene trench in a silicon substrate, and the dual damascene trench comprises an upper first trench and a lower second trench. A buried plate is formed in the silicon substrate to surround the second trench. A node dielectric is formed on a surface of the buried plate, and a collar dielectric is formed on portions of the silicon substrate in the second trench. A buried strap is formed in the second trench, and a trench top oxide (TTO) is formed on the buried strap. A threshold voltage of a metal oxide semiconductor (MOS) transistor of a memory cell is adjusted, and a source/drain (S/D) and a gate of the MOS transistor are formed.

The present invention utilizes a dual damascene trench structure to improve the product reliability. First, the first trench with a larger opening is formed. A spacer is formed underlying the first trench, and then the spacer is utilized as a mask to form the second trench with a smaller opening than the opening of the first trench. Therefore, a line width of the second trench is reduced without being limited by the exposure resolutions. In addition, the first trench of the present invention has a larger line width compared to the conventional trench, thus a precisely control and a uniform shape of the first trench are obtained during an etching process of the first trench. Therefore, the gate in the first trench has a stable channel length to improve the product reliability.

These and other objectives of the present invention will no doubt become obvious to those of ordinary skill in the art after reading the following detailed description of the preferred embodiment that is illustrated in the multiple figures and drawings.

### BRIEF DESCRIPTION OF DRAWINGS

FIG. 1 through FIG. 5 are schematic diagrams in a conventional method of fabricating a DRAM cell.

FIG. 6 through FIG. 12 are schematic diagrams of fabricating a DRAM cell according to the present invention.

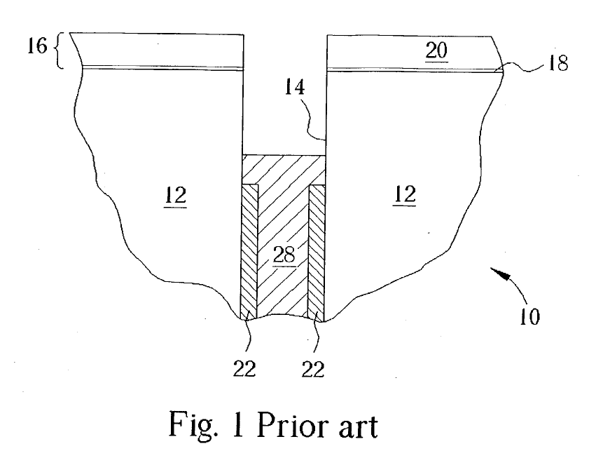

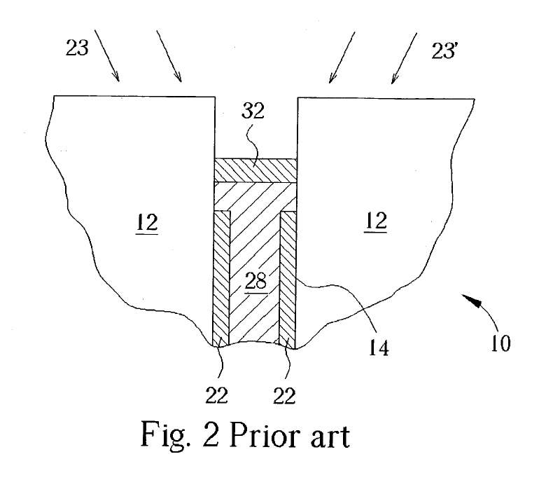

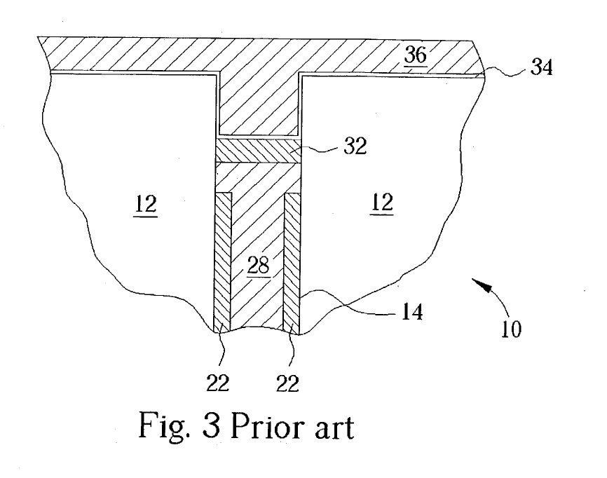

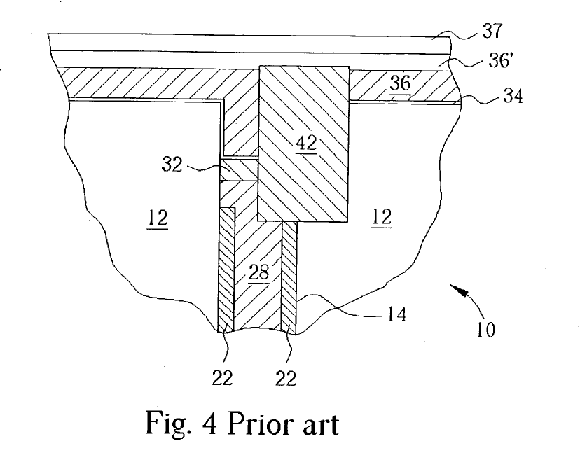

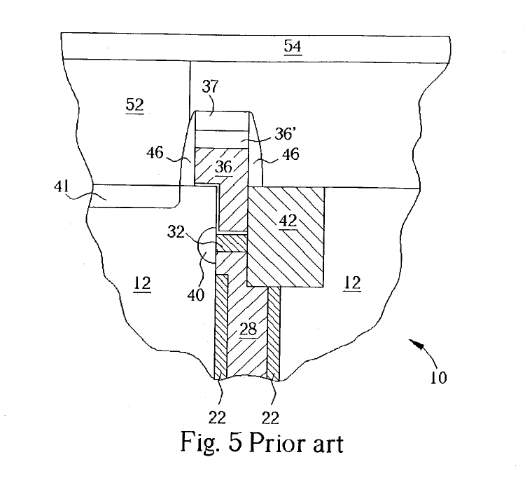

### DETAILED DESCRIPTION

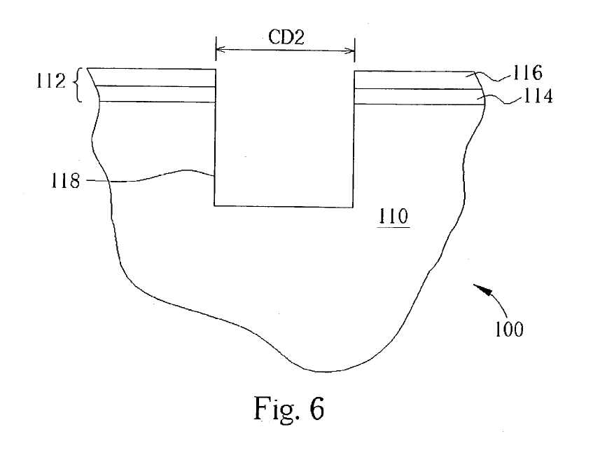

FIG. 6 through FIG. 12 illustrate a method of fabricating a dynamic random access memory (DRAM) cell according to the present invention. Referring to FIG. 6, a semiconductor wafer 100 comprising a silicon substrate 110 is provided and a pad stack 112 is formed on the silicon substrate 110. For example, the semiconductor wafer 100 is a single crystal silicon wafer, a silicon-on insulator (SOI) substrate, an epitaxy substrate or other substrates applied in the semiconductor process. The pad stack 112 comprises a silicon oxide layer 116 and a silicon nitride layer 114. First, a photolithographic process is performed to pattern the pad stack 112. Then, the patterned pad stack 112 is utilized as a mask to etch the silicon substrate 110, thus a first trench 118 is formed in the silicon substrate 110. The first trench 118 has a line width CD2 of about 0.25 micrometers (μm) and a depth ranging from 400 to 600 nanometers (nm).

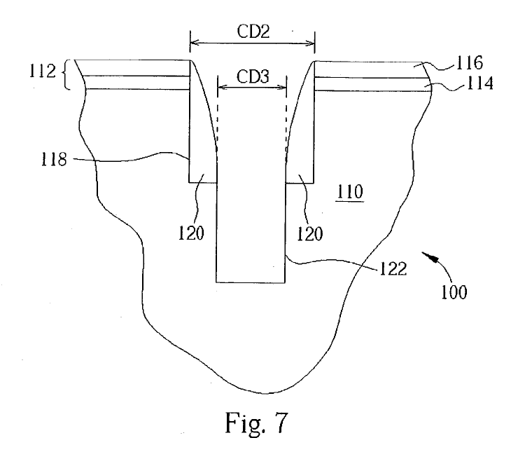

Referring to FIG. 7, a silicon nitride layer (not shown) is deposited on an entire surface of the semiconductor wafer 100 by chemical vapor deposition (CVD) process, and the silicon nitride layer is subsequently etched by an isotropic etching process to form a spacer 120 on a sidewall of the first trench 118. The patterned pad stack 112 and the spacer 120 are utilized as a mask to etch the silicon substrate 110, and then the second trench 122 is formed in the silicon substrate 110, underlying the first trench 118. The second trench 122 has a line width CD3 of about 0.1 μm and a depth ranging from 400 to 600 nm.

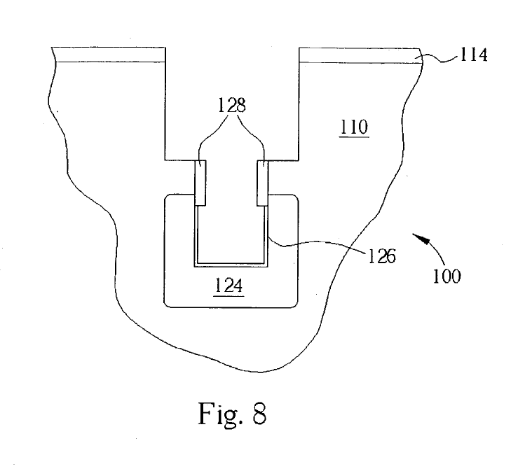

Referring to FIG. 8, an ASG diffusion technique is performed to form a N-type buried plate 124 in the silicon substrate 110 to surround a bottom of the second trench 122. The N-type buried plate 124 is used as a top electrode of a capacitor. The ASG diffusion technique is obvious to those skilled in the art, so further details are omitted. Then, a silicon nitride layer (not shown) is formed on the silicon substrate 110, the first trench 118 and the second trench 122. A transitional layer (not shown), such as a photoresist layer or a doped polysilicon layer is filled in the second trench 122, and a top surface of the transitional layer is approximately aligned with a top surface of the buried plate 124. A wet etching process using hot phosphoric acid as a reaction solution is performed to remove a portion of the silicon nitride layer not covered by the transitional layer to expose a portion of the silicon substrate 110 around an upper portion of the second trench 122.

After the transitional layer is entirely removed, an oxidation process, such as a rapid thermal process (RTP) at a temperature of about 900 to 1000° C. with steam is performed to simultaneously form a first oxide film (not shown) on the silicon nitride layer and a second oxide film, namely a collar dielectric 128 on the exposed silicon substrate 110 in the upper portion of the second trench 122. The second oxide film 128 has a thickness of about 200 to 300 angstroms and is thicker than the first oxide film. The first oxide film and the silicon nitride layer are used as a node dielectric 126, and the collar dielectric 128 is used to reduce parasitic leakage. Following this, the spacer 120 is removed.

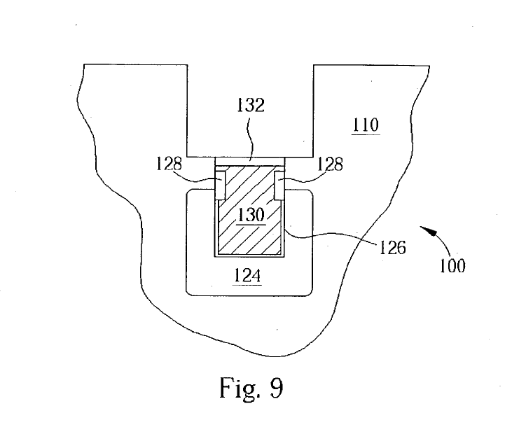

Referring to FIG. 9, a doped polysilicon layer is filled in the second trench 122 to form a buried strap 130, functioning as a storage node. If the above-mentioned transitional layer is made of doped polysilicon, the transitional layer is not removed and is directly used as a portion of the buried strap 130. Then, an oxide layer (not shown) is selectively deposited on the semiconductor wafer 100 by CVD, and a portion of the oxide layer at a bottom of the first trench 118 is thicker than other positions of the oxide layer. After that, an etching process is performed to remove a portion of the oxide layer and a remaining portion of the etched oxide layer is used as a trench top oxide (TTO) layer 132. A top surface of the TTO layer 132 is substantially aligned with a bottom surface of the first trench 118. A thickness of the TTO layer 132 ranges from 10 to 100 nm, and a preferred value ranging from 30 to 40 nm is suggested.

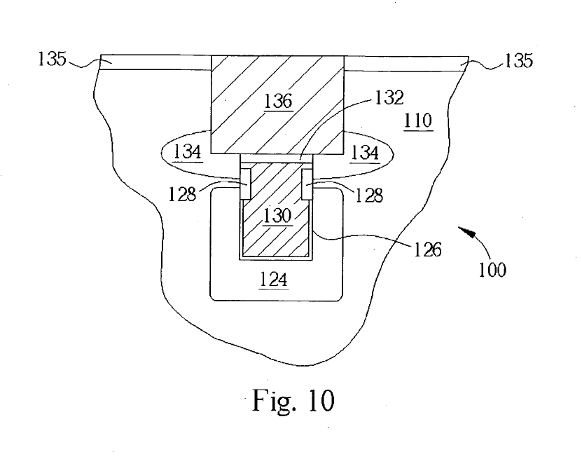

Referring to FIG. 10, a tilt-angle ion implantation process is performed to implant dopants into a gate channel of the first trench 118 to adjust a threshold voltage of a gate. Then, a right-angle ion implantation process is performed to form a source 134 and a drain 135. Alternatively, a thermal diffusion process can also be performed to diffuse dopants in the buried strap 130 to form the source 134, or another tilt-angle ion implantation process can be performed to form the source 134 and the drain 135 concurrently. Following this, the semiconductor wafer 100 is placed in a furnace (not shown) where oxygen (O₂) is introduced as a reaction gas to oxidize a surface of the silicon substrate 100 to form a silicon oxide layer, functioning as a gate insulating layer (not shown) by a dry or wet oxidation process. Then, polysilicon or doped polysilicon is filled in the first trench 118 by CVD and a planarization process is performed to form a gate conductor 136.

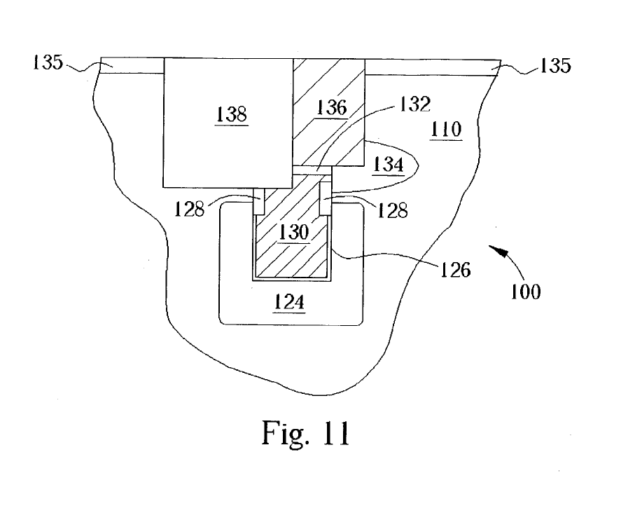

Referring to FIG. 11, a shallow trench isolation (STI) process is performed to form a shallow trench (not shown) overlapping with a portion of the first trench 118. The shallow trench has a depth larger than the TTO layer 132, thus a portion of the buried strap 130 is exposed in the shallow trench. An insulating material, such as a silicon oxide compound is filled in the shallow trench and a planarization process is performed to form a shallow trench isolation 138. Then, another planarization process is performed on the semiconductor wafer 100, and the STI process is completed.

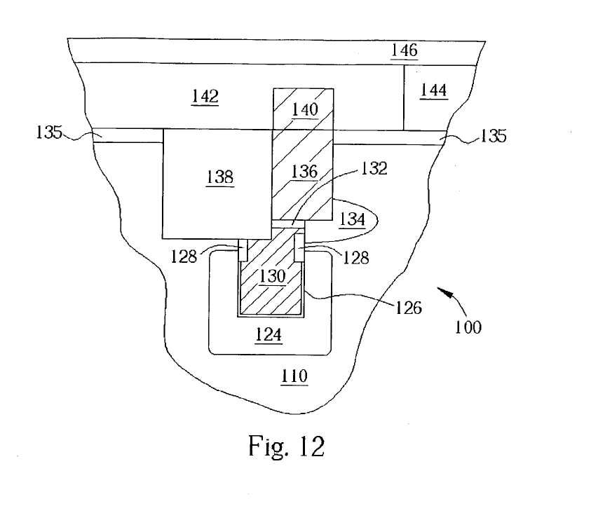

Referring now to FIG. 12, a polysilicon layer (not shown) is deposited on the semiconductor wafer 100, and a photo-etching-process (PEP) is performed to remove a portion of the polysilicon layer to form a word line 140. A dielectric layer 142, a bit line contact plug 144 and a bit line 146 are formed in subsequent processes, therefore a DRAM cell and periphery circuit devices are completed. Due to the above-mentioned techniques for forming the dielectric layer 142, the bit line contact plug 144 and the bit line 146 are obvious to those skilled in the art and have various designs, for example a silicide layer and a top protection layer can be formed on the bit line 146, and a spacer can be formed around the bit line 146, so further details are omitted.

From above, the present invention utilizes the dual damascene trench to improve the conventional problems. The spacer 120 is formed in the first trench 18 that has a larger opening, and then the second trench 122 with a smaller opening is formed using the spacer 120 as an etching mask. Therefore, a line width of the second trench 122 is reduced without being limited by the exposure resolution.

In comparison with the conventional trench, the dual damascene trench structure can reduce the line width of the second trench to benefit developments of a process below 0.1 μm. In addition, the first trench of the present invention has a larger line width CD2, thus a precisely depth control is obtained during a poly recess etching to fabricate a bottom capacitor structure, and the length of the gate formed later is not affected. Therefore, the gate formed in the first trench has a stable channel length to improve the product reliability.

Those skilled in the art will readily observe that numerous modification and alterations of the device may be made while retaining the teachings of the invention. Accordingly, the above disclosure should be construed as a limited only by the metes and bounds of the appended claims.

What is claimed is:

1. A method of fabricating a dynamic random access memory (DRAM) cell, the method comprising:
providing a silicon substrate;
forming a dual damascene trench in the silicon substrate, the dual damascene trench comprising an upper first trench and a lower second trench;
forming a buried plate in the silicon substrate to surround the second trench;
forming a node dielectric on a surface of the buried plate;
forming a collar dielectric on portions of the silicon substrate in the second trench;
forming a buried strap in the second trench;
forming a trench top oxide (TTO) on the buried strap;
adjusting a threshold voltage of a metal oxide semiconductor (MOS) transistor of the memory cell;
forming a source and a drain of the MOS transistor; and
forming a gate of the MOS transistor in the first trench.

2. The method of claim 1 wherein a method of forming the dual damascene trench comprises:
forming a patterned pad stack on the silicon substrate;
utilizing the patterned pad stack as a first mask to etch the silicon substrate and form the first trench in the silicon substrate;
forming a spacer on a sidewall of the first trench; and
utilizing the patterned pad stack and the spacer as a second mask to etch the silicon substrate and form the second trench in the silicon substrate underlying the first trench.

3. The method of claim 2 wherein the pad stack comprises a silicon oxide layer and a silicon nitride layer, and the spacer comprises a silicon nitride compound.

4. The method of claim 1 wherein the buried plate is formed by an arsenic silicate glass (ASG) diffusion technique.

5. The method of claim 1 wherein a method of forming the collar dielectric and the node dielectric comprises:
forming a dielectric layer on the silicon substrate and the dual damascene trench;
forming a transitional layer to fill the second trench,a top surface of the transitional layer being approximately aligned with a top surface of the buried plate;
removing portions of the dielectric layer not covered by the transitional layer to expose portions of the silicon substrate around an upper portion of the second trench and around the first trench; and
performing an oxidation process to simultaneously form a first oxide film on the dielectric layer and a second oxide film on the exposed substrate in the dual damascene trench, a thickness of the second oxide film being thicker than a thickness of the first oxide film;
wherein the first oxide film and the dielectric layer are used as the node dielectric, and the second oxide film is used as the collar dielectric.

6. The method of claim 5 wherein the transitional layer is a photoresist layer, and the oxidation process is performed after the transitional layer is entirely removed.

7. The method of claim 5 wherein the transitional layer is made of doped polysilicon and the transitional layer is used as a portion of the buried strap.

8. The method of claim 1 wherein the buried strap is made of doped polysilicon.

9. The method of claim 1 wherein the method further comprises a tilt-angle ion implantation process to adjust the threshold voltage, and a right-angle ion implantation process to form the source and the drain of the MOS transistor.

10. The method of claim 1 wherein the source and the drain of the MOS transistor are formed by an ion implantation process.

11. The method of claim 1 wherein a method of forming the gate comprises:
forming a first conductive layer to fill the dual damascene trench;
performing a shallow trench isolation (STI) process to form at least one shallow trench isolation in the silicon substrate, the shallow trench isolation being used to isolate the memory cell from other devices;
forming a second conductive layer on the silicon substrate; and
performing a photo-etching-process (PEP) to remove a portion of the second conductive layer;
wherein the first conductive layer is used as the gate of the MOS transistor, and the remaining portion of the etched second conductive layer is used as a word line of the DRAM cell.

12. The method of claim 1 wherein the silicon substrate comprises a single crystal silicon wafer, a silicon-on insulator (SOI) substrate or an epitaxy substrate.

13. A method of fabricating a dynamic random access memory (DRAM) cell, the method comprising:
providing a silicon substrate, the silicon substrate comprising a patterned pad stack thereon;
utilizing the patterned stack as a first mask to etch the silicon substrate and form a first trench in the silicon substrate;
forming a spacer on a sidewall of the first trench;
utilizing the patterned pad stack and the spacer as a second mask to etch the silicon substrate and form a second trench underlying the first trench;
forming a buried plate in the silicon substrate to surround the second trench;
forming a dielectric layer on the silicon substrate, the first trench and the second trench;
forming a transitional layer to fill the second trench,a top surface of the transitional layer being approximately aligned with a top surface of the buried plate;
removing portions of the dielectric layer not covered by the transitional layer to expose portions of the silicon substrate around an upper portion of the second trench;
performing an oxidation process to simultaneously form a first oxide film on the dielectric layer and a second oxide film on the exposed silicon substrate in the second trench, a thickness of the second oxide film being thicker than a thickness of the first oxide film;
removing the spacer;
forming a buried strap in the second trench;
forming a trench top oxide (TTO) on the buried strap;
removing the pad stack;
forming a source and a drain of a MOS transistor; and
forming a gate of the MOS transistor in the first trench.

14. The method of claim 13 wherein the pad stack comprises an upper silicon oxide layer and a lower silicon nitride layer, and the spacer comprises a silicon nitride compound.

15. The method of claim 13 wherein the buried plate is formed by an arsenic silicate glass (ASG) diffusion technique.

16. The method of claim 13 wherein the first oxide film and the dielectric layer are used as a node dielectric of a capacitor of the memory cell, and the second oxide film is used as a collar dielectric of the memory cell.

17. The method of claim 13 wherein the transitional layer is a photoresist layer, and the oxidation process is performed after the transitional layer is entirely removed.

18. The method of claim 13 wherein the transitional layer is made of doped polysilicon and the transitional layer is used as a portion of the buried strap.

19. The method of claim 13 wherein the method further comprises a tilt-angle ion implantation process to adjust a threshold voltage of the MOS transistor.

20. The method of claim 13 wherein the source and the drain of the MOS transistor are formed by an ion implantation process.

21. The method of claim 13 wherein a method of forming the gate comprises:
forming a first conductive layer to fill the dual damascene trench;
performing a shallow trench isolation (STI) process to form at least one shallow trench isolation in the silicon substrate, the shallow trench isolation being used to isolate the memory cell from other devices;
forming a second conductive layer on the silicon substrate; and
performing a photo-etching-process (PEP) to remove a portion of the second conductive layer;
wherein the first conductive layer is used as the gate of the MOS transistor, and the remaining portion of the etched second conductive layer is used as a word line of the DRAM cell.
